(19) United States
(12) Patent Application Publication
(10) Pub. No.: US 2010/0200045 A1
(43) Pub. Date: Aug. 12, 2010

(54) SOLAR POWER SYSTEM AND METHOD OF MANUFACTURING AND DEPLOYMENT

(76) Inventor: Kim W. Mitchell, San Ramon, CA (US)

Correspondence Address: MARTINE PENILLA & GENCARELLA, LLP, 710 LAKEWAY DRIVE, SUITE 200, SUNNYVALE, CA, 94085, US

(21) Appl. No.: 12/368,061

(22) Filed: Feb. 9, 2009

(51) Int. Cl. H01L 31/052; H01R 43/00

(52) U.S. Cl. 136/246; 29/825

(57) ABSTRACT

A method of forming a photovoltaic module including providing a first layer, applying a first adhesive layer to the first layer, securing a first layer of conductors on the sealing layer, securing a set of photovoltaic cells on the first layer of conductors, electrically coupling at least a portion of the photovoltaic cells in parallel, securing a set of interconnecting conductors to the first layer of conductors, securing a second layer of conductors to the photovoltaic cells and the interconnecting conductors, electrically coupling the interconnecting wires to the first layer of conductors and the second layer of conductors, wherein in at least one of the first layer of conductors, the second layer of conductors and the interconnecting conductors are non-flat electrical wires and applying a final layer over the of photovoltaic cells and the first layer of conductors, the interconnecting conductors and second layer of conductors. A method of forming a large scale photovoltaic module array is also disclosed. A method of connecting multiple photovoltaic cells is also disclosed. A photovoltaic module is also disclosed.

### BACKGROUND

The present invention relates generally to solar-photovoltaic power systems, and more particularly, to methods and systems for building, installing and operating a photovoltaic power system.

Practical, large scale, efficient solar power has been sought for nearly as long as ancient man gazed into the bright sunlight, enjoying the sun's warmth and energy as it warmed him. At the same time he felt the cold dread of the sunless, withering night that would be upon him in a few hours. He wished for a way to hold the light and warmth of the sun for use during those cold nights.

Solar power technologies have been divided into two basic categories: solar thermal and solar photovoltaic. Solar thermal includes systems that collect the energy from the sun and store or use it in the form of heat.

Solar photovoltaic systems collect energy from the sun and convert that solar energy directly to electricity. The electricity can then be used or stored as desired. The present application focuses on solar photovoltaic systems and methods of manufacture.

Typical solar photovoltaic systems are relatively inefficient as they convert less than about ten percent of the light energy that impinges on them to electrical power. There are many reasons for the inefficiency including solar cell space wasting arrangements of solar cells on the solar module, inefficient wiring systems between the solar cells and between each solar module.

The typical solar photovoltaic systems are also very costly to produce and deploy in a large scale fashion. A large scale for purposes of discussion herein include a solar photovoltaic power production facility capable of producing 5 megawatts or more. For example many typical solar photovoltaic modules are limited to 50-200 watts of power and therefore require between 100,000 to 25,000 modules coupled together to product the desired power output. Coupling 100,000 modules together is a complex process and is inefficient due to energy losses, excess wiring required to tie the modules together and complex construction of a support structure.

In view of the foregoing, there is a need for a more easily and efficiently deployed, large-scale solar power system.

### SUMMARY

Broadly speaking, the present invention fills these needs by providing improved photovoltaic systems and methods for manufacturing and deploying said systems will now be described. It should be appreciated that the present invention can be implemented in numerous ways, including as a process, an apparatus, a system, computer readable media, or a device. Several inventive embodiments of the present invention are described below.

One embodiment provides a method of forming a photovoltaic module. The method includes providing a first layer, applying a first adhesive layer to the first layer, securing a first layer of conductors on the sealing layer, securing a set of photovoltaic cells on the first layer of conductors, electrically coupling at least a portion of the photovoltaic cells in parallel, securing a set of interconnecting conductors to the first layer of conductors, securing a second layer of conductors to the photovoltaic cells and the interconnecting conductors, electrically coupling the interconnecting wires to the first layer of conductors and the second layer of conductors, wherein in at least one of the first layer of conductors, the second layer of conductors and the interconnecting conductors are non-flat electrical wires and applying a final layer over the of photovoltaic cells and the first layer of conductors, the interconnecting conductors and second layer of conductors.

The non-flat conductors can include at least one reflective surface. The reflective surface can include a reflective coating. The method can also include installing a positive electrical connector and a negative electrical connector on an opposing side of a backing plate from the plurality of photovoltaic cells. The positive and negative electrical connectors can have a shape that substantially prevents torque to the plurality of photovoltaic cells.

Applying the final layer over the photovoltaic cells and the first layer of conductors, the interconnecting conductors and second layer of conductors can include sealing the photovoltaic cells and the first layer of conductors, the interconnecting conductors and second layer of conductors between the final layer and the first layer.

The final layer can include more than one layer and wherein at least one of the more than one layer can include a second adhesive layer. The first adhesive layer can support and encapsulate the photovoltaic cells. At least one of the first layer or the final layer can include a first thermally conductive layer and wherein the first thermally conductive layer thermally couples the photovoltaic cells to an exterior surface of the photovoltaic module. The first thermally conductive layer can be metallic and can form a first exterior surface of the photovoltaic module opposite from a second exterior surface of the photovoltaic module and the second exterior surface of the photovoltaic module is oriented toward a light source. The first thermally conductive layer can include a second thermally conductive layer between the photovoltaic cells and the first thermally conductive layer. The second thermally conductive layer can electrically insulate the photovoltaic cells from the first thermally conductive layer.

The photovoltaic cells and the interconnecting conductors can be formed in a first layer and the first layer of conductors are formed in a second layer adjacent to a first surface of the photovoltaic cells and the second layer of conductors are formed in a third layer adjacent to a second surface of the photovoltaic cells, the second surface of the photovoltaic cells being opposite from the first surface of the photovoltaic cells. At least one of the first layer or the final layer can include a conforming cover layer. The conforming cover layer conforms to the non-flat electrical wires. At least one of the first layer or the final layer can include a cover layer over a photovoltaically active surface of the photovoltaic cells and wherein the cover layer includes recesses for the non flat wires on the photovoltaically active surface of the photovoltaic cells. The method can also include securing the photovoltaic module to a support member. The method can also include forming the support member on site.

Another embodiment provides a method of forming a large scale photovoltaic module array including forming at least one support member onsite, securing the at least one support member to a foundation structure, securing multiple photovoltaic modules to the at least one support member and electrically coupling the plurality of photovoltaic modules.

Yet another embodiment provides a method of connecting multiple photovoltaic cells including electrically coupling a first surface of the photovoltaic cells to a first conductive layer, the first surface of the photovoltaic cells having a first polarity and electrically coupling a second surface of the photovoltaic cells to a second conductive layer, the second surface of the photovoltaic cells having a second polarity, the second surface of the photovoltaic cells being opposite the first surface, wherein at least one of the first conductive layer or the second conductive layer includes non-flat electrical wires. The non-flat electrical wires can include at least one optically reflective surface.

Still another embodiment provides a photovoltaic module including a first layer, a first adhesive layer on the first layer, a first layer of conductors on the sealing layer, multiple photovoltaic cells on the first layer of conductors wherein the first layer of conductors electrically couple at least a portion of the photovoltaic cells in parallel, multiple interconnecting conductors electrically coupled to the first layer of conductors, a second layer of conductors electrically coupled to the photovoltaic cells and the plurality of interconnecting conductors, wherein in at least one of the first layer of conductors, the second layer of conductors and the plurality of interconnecting conductors are non-flat electrical wires and a final layer over the photovoltaic cells and the first layer of conductors, the interconnecting conductors and second layer of conductors.

Other aspects and advantages of the invention will become apparent from the following detailed description, taken in conjunction with the accompanying drawings, illustrating by way of example the principles of the invention.

### BRIEF DESCRIPTION OF THE DRAWINGS

The present invention will be readily understood by the following detailed description in conjunction with the accompanying drawings.

FIG. 1A is a simplified exemplary diagram of a typical PV module, in accordance with an embodiment of the present invention.

FIG. 1B is a sectional view 1B-1B of the typical PV module, in accordance with an embodiment of the present invention.

FIG. 2A is a simplified exemplary diagram of the improved PV module, in accordance with an embodiment of the present invention.

FIGS. 2B and 2C are sectional views 2B-2B of the improved PV module, in accordance with an embodiment of the present invention.

FIG. 2D is a sectional view 2D-2D of the improved PV module, in accordance with an embodiment of the present invention.

FIG. 2E is a simplified diagram of an exemplary PV cell, in accordance with an embodiment of the present invention.

FIGS. 2F and 2G are sectional views 2F-2F and 2G-2G, respectively of the exemplary PV cell, in accordance with an embodiment of the present invention.

FIG. 3A is a simplified drawing of multiple improved PV modules coupled together and folded a first configuration, in accordance with an embodiment of the present invention.

FIG. 3B is a simplified drawing of multiple improved PV modules folded a second configuration, in accordance with an embodiment of the present invention.

FIG. 3C is a simplified drawing of an improved PV modules coupled to an optically reflective panel, in accordance with an embodiment of the present invention.

FIG. 4A is a detailed view of the electrical connector, in accordance with an embodiment of the present invention.

FIG. 4B is a cross sectional view 4B-4B of the detailed view of the electrical connector, in accordance with an embodiment of the present invention.

FIG. 4C illustrates multiple improved PV modules coupled together in an improved PV module array, in accordance with an embodiment of the present invention.

FIG. 5A is a simplified diagram of the support member forming system, in accordance with an embodiment of the present invention.

FIG. 5B is a cross section of the support member, in accordance with an embodiment of the present invention.

FIG. 5C is a simplified diagram of a deployment system, in accordance with an embodiment of the present invention.

FIG. 6 is a flowchart of the method operations of forming a photovoltaic module, in accordance with an embodiment of the present invention.

FIG. 7 is a flowchart of the method operations of deploying a photovoltaic module, in accordance with an embodiment of the present invention.

### DETAILED DESCRIPTION

Several exemplary embodiments for improved photovoltaic systems and methods for manufacturing and deploying said systems will now be described. It will be apparent to those skilled in the art that the present invention may be practiced without some or all of the specific details set forth herein.

One approach to an efficient, lower cost, large scale deployment of photovoltaic (PV) systems uses an improved PV module. Another approach is an improved installation process and structure for typical PV modules or in combination with the improved PV module.

### Improved PV Module

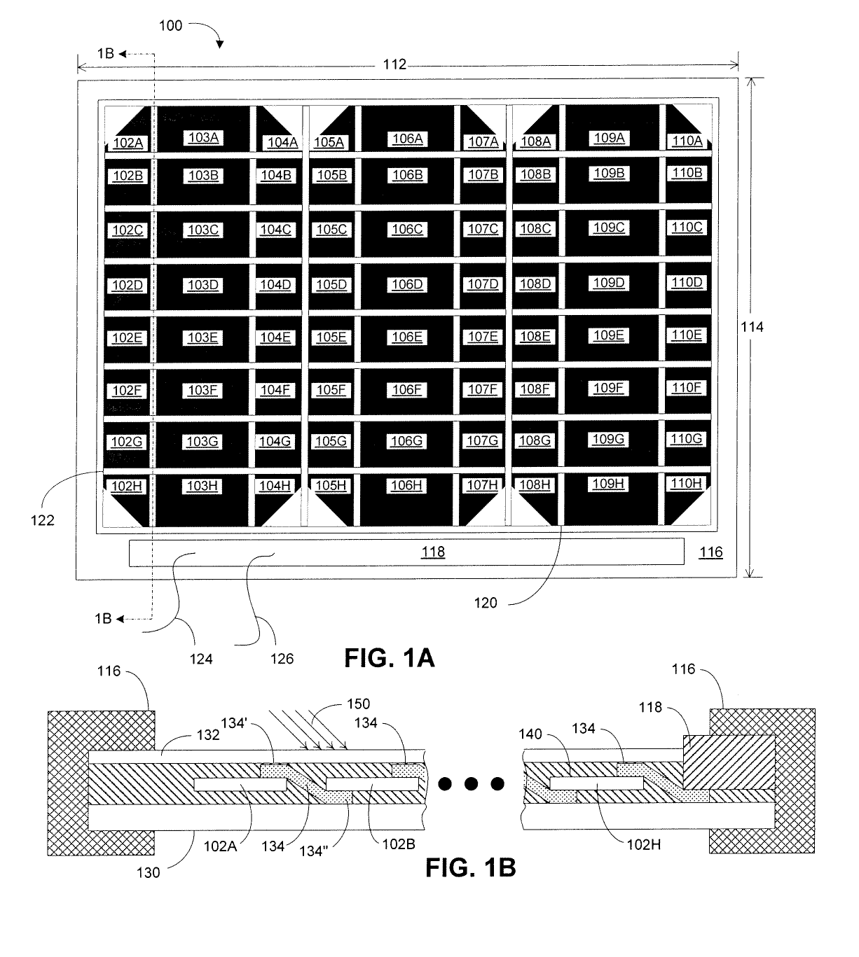

Typical PV modules are manufactured using a glass front and in some cases, a glass substrate to provide a glass/glass encapsulation. FIG. 1A is a simplified exemplary diagram of a typical PV module 100, in accordance with an embodiment of the present invention. FIG. 1B is a sectional view 1B-1B of the typical PV module 100, in accordance with an embodiment of the present invention. The typical PV module 100 includes multiple separate photovoltaic cells 102A-110H. The typical PV module 100 also includes a frame 116. The frame 116 wraps around the edges of the PV module 100 and provides structural support and stiffening so as to provide mechanical attachment points for the PV module 100.

Referring now to FIG. 1B, a covering glass layer 132 can form a top surface of the PV module 100. The covering glass layer 132 transmits the light 150 to the PV cells 102A-110H. A stabilizing media 140 can be formed of one of more layers of ethylene vinyl acetate (EVA) to hermetically seal and support and secure the PV cells 102A-110H to the covering glass layer 132. The typical nominal thickness of this EVA is 18 mils (0.008 inches). The typical PV module 100 also includes a backing plate 130 consisting of glass or a multilayer encapsulant film which completes the sealed package of the PV module.

The PV cells 102A-102H are connected in series. The PV cells 102A-102H are interconnected by metal ribbon leads 134. The metal ribbon leads 134 alternate from the top surface of a first PV cell to a bottom surface of a second PV cell. By way of example, metal ribbon lead 134 connects first end 134′ to a negative terminal of PV cell 102A on the top surface of PV cell 102A and a second end 134″ to a positive terminal of PV cell 102B on the bottom surface of PV cell 102B.

The metal ribbon leads 134 are typically conductive ribbon. Typically the interconnecting ribbons 134 are very thin so as to be flexible and easy to install alternating from top to bottom of the PV cells connected in series as shown.

The glass backing plate 130 and the covering glass layer 132 adds substantial weight and thermal mass to the PV module 100. The frame 116 also increases the volume of the PV module 100 and limits the number of PV modules that can be placed in a particular shipping container or in a vehicle or on a structure when deployed. The frame 116 can also unduly complicate the mounting process and mounting requirements of the PV module 100.

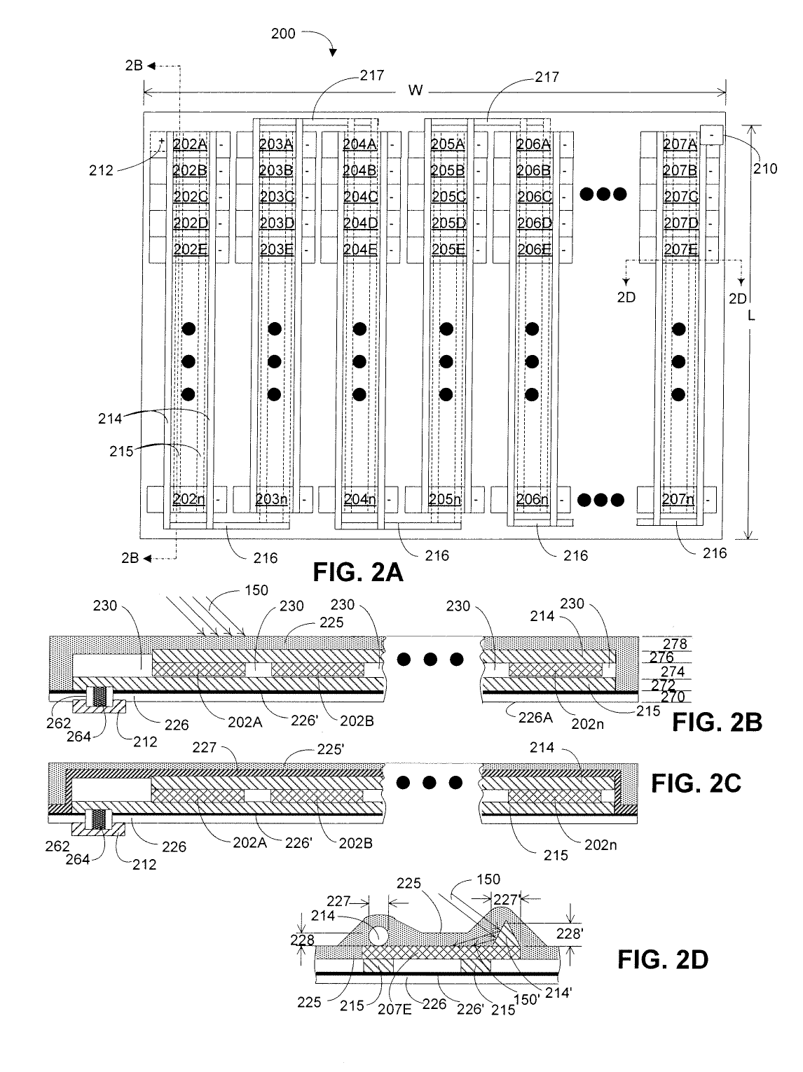

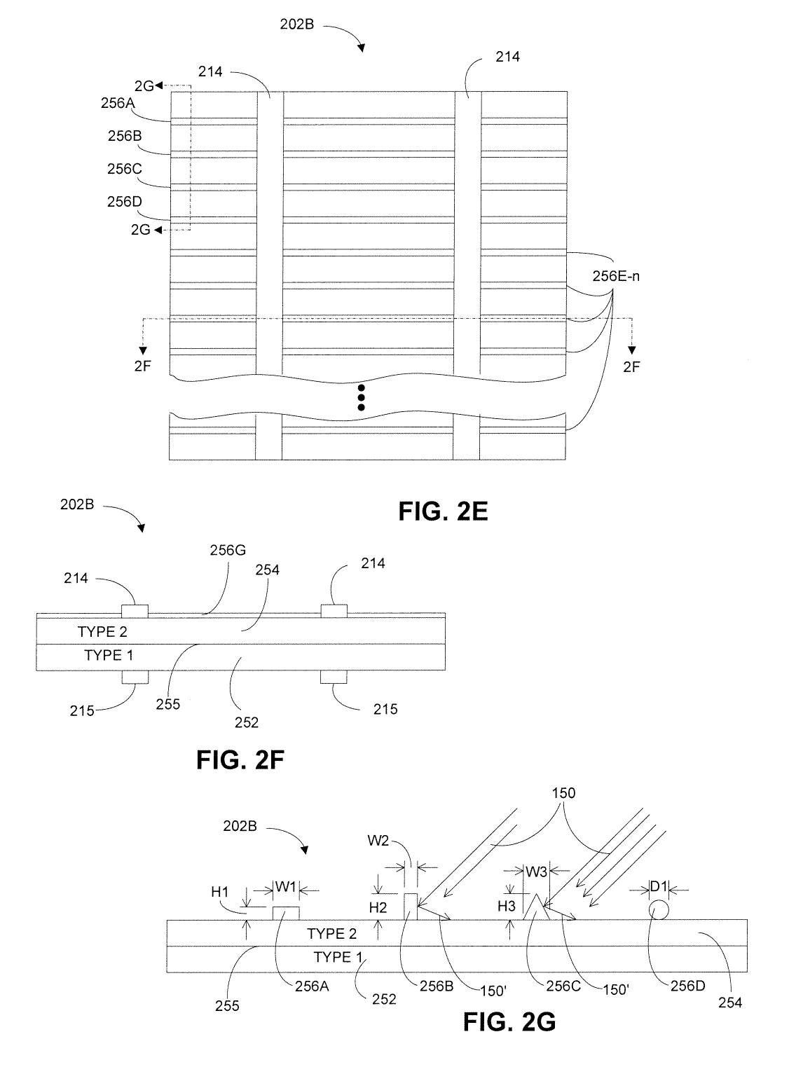

An improved PV 200 module includes several improved aspects including larger effective area (e.g., less wasted area), a simplified design, a thinner design and a lighter overall weight as compared to the typical PV module 100. FIG. 2A is a simplified exemplary diagram of the improved PV module 200, in accordance with an embodiment of the present invention. FIGS. 2B and 2C are sectional views 2B-2B of the improved PV module 200, in accordance with an embodiment of the present invention. FIG. 2D is a sectional view 2D-2D of the improved PV module 200, in accordance with an embodiment of the present invention. FIG. 2E is a simplified diagram of an exemplary PV cell 202B, in accordance with an embodiment of the present invention. FIGS. 2F and 2G are sectional views 2F-2F and 2G-2G, respectively of the exemplary PV cell 202B, in accordance with an embodiment of the present invention.

The improved PV module 200 is a significant departure from the typical PV module 100 designs. Significant cost drivers including the module frame 116, the electrical junction box 118 and the covering glass layer 132 are eliminated. The typical PV modules 100 include the covering glass layer 132 and the backing plate 130 which can include a glass layer. The improved PV module 200 eliminates both the covering glass layer 132 and the glass backing plate 130. Any type of PV cell (e.g., silicon, thin film, etc.) can be used in the improved PV module 200 to provide more efficient output as will be described in more detail below.

The improved PV module 200 is a substantially frameless design and is thinner and lighter weight as compared to the typical PV module 100. The improved PV module 200 does not require a frame for mechanical support. It should be understood that an edging or a frame could be included for packaging, encapsulation, durability and/or handling purposes. In the improved PV module 200, the PV cells 202A-207n are supported from the back using a thin, light weight, metal or composite backing plate 226. The thin metal or composite backing plate 226 improves the heat sinking of the PV cells. The normal operating cell temperature (NOCT) for the PV cells 202A-207n is typically higher than the ambient temperature due to absorption of the light 150 that impinges on the PV cells. As the temperature of the PV cells 202A-202n increases, the PV cell efficiency is reduced. The NOCT for the improved PV module 200 is lower than the typical PV module 100 due to improved heat sinking and dissipation performance of the backing plate 226 as compared to the typical PV module 100. As a result, the improved PV module 200 has more efficient performance as compared to a typical PV module 100.

The improved PV module 200 is between about one half and one fourteenth the thickness of typical PV modules 100. The area weight of the improved PV module 200 is on the order of 6 kg/m² and is between about one half to one third the area weight of typical PV modules 100. The reduced weight and volume of the improved PV module 200 also reduces the shipping, storage and handling costs. The reduced weight and volume of the improved PV module 200 also eases field installation or deployment. As a result, the deployment and installation costs are correspondingly reduced.

The backing plate 226 can be aluminum or a similar metal or composite material. The backing plate 226 can be about 2 mm thick. The backing plate 226 can be thinner (e.g., less than about 1 mm thick) or thicker (e.g., more than about 5 mm or thicker). Other back support materials, both metal and non-metal, and thicknesses could also be used depending upon the application. The back surface 226A of the backing plate 226 can be textured or ribbed or have a repeating pattern or a random pattern such that the surface area of the back surface 226A can be increased. The increased surface area of the back surface 226A improves the thermal transfer to the environment.

The improved PV module 200 also includes a thin, optically transmissive polymer cover film 225 instead of the covering glass layer 132 of the typical PV module 100. The cover film 225 can be a fluoropolymer film such as those marketed under the trade names of Dupont Tefzel or Teflon film and similar films. The fluoropolymer films have a lower index of refraction (e.g., about 1.3 to about 1.5) as compared to typical index of refraction of glass of about 1.5. The lower index of refraction of these films can also reduce an optical reflection loss as compared to the covering glass layer 132 of the typical PV module 100. By way of example, the lower index of refraction of the cover film 225 transmits up to about 95% of the available light to the PV cells 202A-207n as compared to a low iron covering glass layer 132 transmitting about 85%. A typical low iron covering glass layer has less than about 0.2 percent iron. The cover film 225 also eliminates the requirement for low iron glass which further reduces the material costs.

The cover film 225 can include more than one layer 225′ and 227. One or more of the layers 225′ and 227 can include optically clear (e.g., less than about 2% optical absorption) potants, very thin glass (e.g., less than about 3 mm thick and preferably less than about 1 mm thick), transparent polycarbonate, acrylic or other plastic sheets, special surface textures and other suitable front encapsulating layers could be considered. The special surface textures can include geometric patterns which promote light transfer into the photovoltaically active cell areas of the PV cells 202A-207n. By way of example, the geometric patterns can include linear triangular shapes or two dimensional pyramid shapes. These shapes reflect the incident light 150 and if oriented correctly the reflected light impinges on the photovoltaically active area of the PV cells 202A-207n. For architectural or aesthetic purposes a filter layer or colored films could be included the more than one layer 225′ and 227 to provide a desired appearance.

The more than one layer 225′ and 227 of the improved PV module 200 can include one or more layers of ethylene vinyl acetate (EVA). Due to the simpler design of the improved PV module 200, layers of EVA thinner than 18 mils can be used. The thinner layers can further reduce the cost of the improved PV module 200. By way of example, the EVA can be between less than about 3 mils and less than 18 mils. In addition, given the capacity constraints in the EVA industry, the amount of the improved PV modules 200 can increased significantly by using thinner EVA layers.

Layers of EVA having a thickness of less than about 18 mils have difficulty supporting themselves and can be difficult to handle during PV module manufacturing. One solution is to bond a thin (e.g., less than about 8 mil thick) EVA layer 227 to the cover film 225′. This reduces the cost of the PV module 200 and the manufacturing process is simplified. EVA can also be used to fill in spaces 230 and support and encapsulate the PV cells 202A-207n. As the PV cells 202A-207n and the conductive layers are encapsulated the EVA can flow into and fill the spaces 230 between the PV cells 202A-207n and the conductive layers.

A thermally conductive, electrically insulating material 226′ (e.g., zinc oxide or similar material) can be added between the PV cells 202A-207n and the backing plate 226 to improve the thermal coupling from the PV cells to the backing plate.

The improved PV module 200 can have any size (length L and width W) that is practical. By way of example the improved PV module 200 can have a width or length of between about 8 feet (about 2.4 m) and about 4 feet (about 1.2 m) as is consistent with typical construction sizes and equipment, for ease of installation, especially for residential and commercial installations. For larger utility scale installations (e.g., 5-50 megawatt or larger) the improved PV module 200 size could be increased to whatever dimension is most practical for the application. Linear dimensions of about 12 feet (about 3.6 m) to about 20 feet (about 6 m) are well within the scale of sizes envisioned. Other applications of the improved PV module 200 could drive a need for smaller (less than 4 feet) or larger (greater than about 20 feet) sizes.

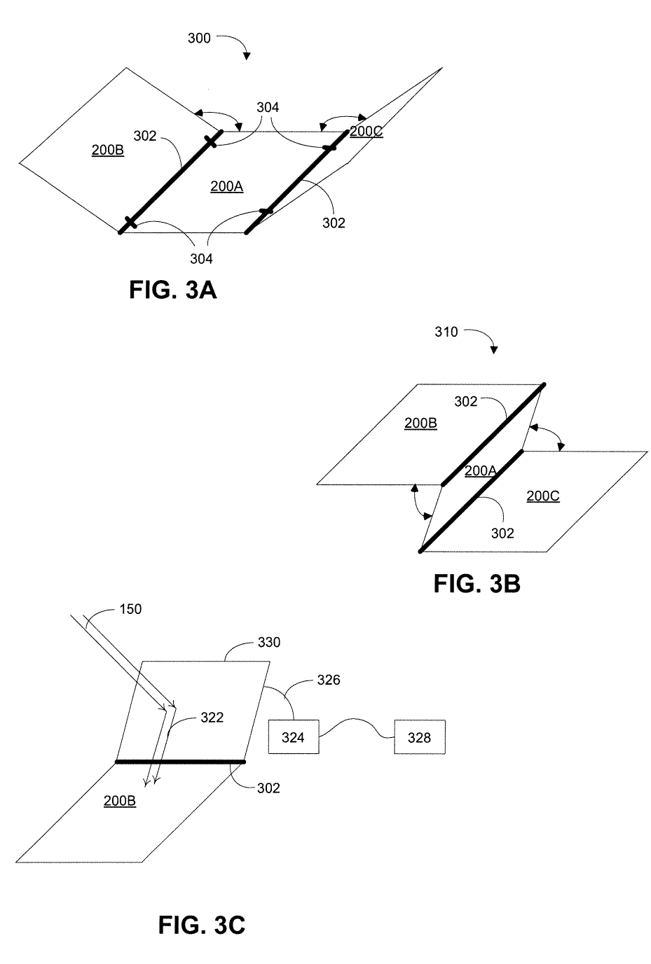

The improved PV module 200 does not have a frame and therefore can easily be coupled to one or more PV modules 200 by hinges or similar flexible coupling. FIG. 3A is a simplified drawing of multiple improved PV modules 200 coupled together and folded in a first configuration 300, in accordance with an embodiment of the present invention. FIG. 3B is a simplified drawing of multiple improved PV modules 200 folded in a second configuration 310, in accordance with an embodiment of the present invention. The multiple PV modules 200A, 200B, 200C can be folded such as for transport and then unfolded for use. By way of example, two PV modules 200A, 200B can be hinged together and folded. Three PV modules 200A, 200B and 200C can be hinged together and folded with the outer modules 200B, 200C folded into the center module 200A, or in a “Z” fold configuration 310.

Electrical coupling between each of the hinged coupled PV modules 200A, 200B, 200C could be made through the hinge 302 such as through flexible wiring or cables or other appropriate means. In a fixed PV array installation, the improved PV modules 200 reduce the number of electrical interconnections required to be made onsite, thus, reducing field installation time and labor costs. In a portable or temporary deployment purpose where the improved PV modules 200A, 200B, 200C can be folded into a compact configuration 300, 310 as described above. The folded PV modules 200A, 200B, 200C can be deployed elsewhere.

One or more locks or latches 304 can be included to prevent the hinged joint 302 between the PV modules 200A, 200B, 200C from moving in the folded configuration. The latch or locking mechanism 304 could also be used to prevent the hinged joint 302 between the PV modules 200A, 200B, 200C from moving in the unfolded configuration.

FIG. 3C is a simplified drawing of an improved PV modules 200 coupled to an optically reflective panel 330, in accordance with an embodiment of the present invention. One or more optically reflective panels 330 can be attached to corresponding one or more sides of a PV module 200. The one or more optically reflective panels 330 can be mechanically coupled to a corresponding side of the PV module 200 with a hinge 302 or other suitable mechanical attachment. The one or more optically reflective panels can be fixed at a selected angle or can be movable. A movable optically reflective panel can be coupled to an actuating system 324, 326, 328 capable of moving the movable optically reflective panel 330 so as to track the light source as may be necessary due to time of day, seasons of the year and even weather conditions. The one or more optically reflective panels 330 increase the amount of light 150 incident on the PV module 200 SO as to increase power output by reflecting light 322 on to the PV module.

### Wiring System

The conventional method for series electrical interconnecting PV cells is to string one or more metal ribbon leads from a first terminal the top of one PV cell to a second terminal on the bottom of the adjacent PV cell. Referring again to FIG. 1B, a metal ribbon lead 134 connects a negative terminal of PV cell 102A on the top surface of PV cell 102A to a positive terminal of PV cell 102B on the bottom surface of PV cell 102B.

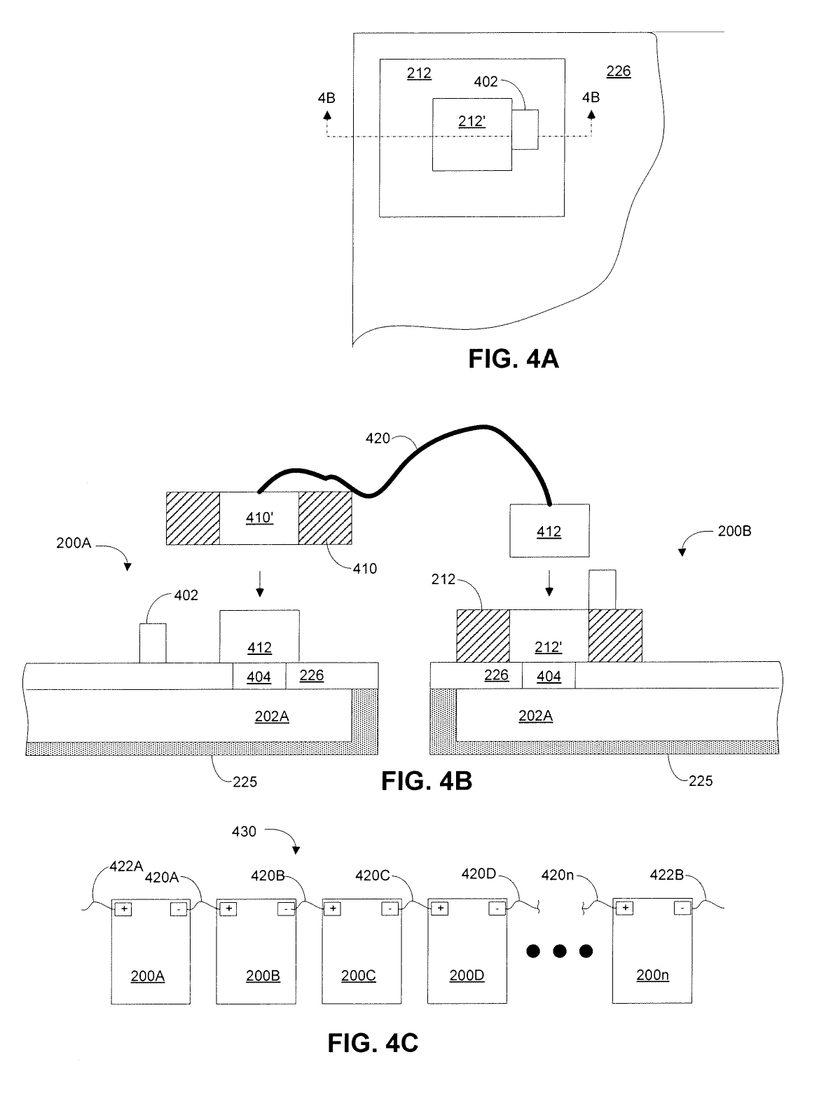

An alternative approach electrically couples all PV cells in a given column or row in parallel. By way of example and with reference to FIG. 2A, each of the PV cells 202A-202n in a column are coupled in parallel by wires 214 across the top surface and wires 215 across the bottom surface of the PV cells 202A-202n. The columns are coupled in series to the adjacent columns. By way of example, the column of PV cells 202A-202n are coupled in series with the column of PV cells 203A-203n by wire 216. More specifically, wire 216 couples the wires 214 from the top surface of the PV cells 202A-202n to the wire 215 on the bottom surface of PV cells 203A-203n. Similarly, wire 217 couples the wires 214 from the top surface of the PV cells 203A-203n to the wire 215 on the bottom surface of PV cells 204A-204n. As a result the coupled PV cells 202A-207n deliver a positive terminal 212 and a negative terminal 210 at corresponding locations on the improved PV module 200 such that coupling one improved PV module to another requires a minimum length coupling cable as will be described in more detail in FIG. 4C below.

Coupling the columns of PV cells with wires 216 and 217 minimizes the wire length and simplifies assembly as the wires 216 and 217 can be placed at the same time as the PV cells 202A-207n. Coupling the columns of PV cells with wires 216 and 217 simplifies assembly as the wires 216 and 217 interconnect with wires 214 and 215 more easily than the flat ribbons leads 134. More specifically, in one embodiment, the wires 216 and 217 can lay on top of wires 215 and wires 214 can lay on top of the wires 216 and 217.

The coupling the columns in series increases the voltage. The new approach significantly simplifies the cell string interconnection process and associated equipment. Appropriate bypass diodes could also be installed along the module edges. Bypass diodes electrically protect the PV cells in the event of partial shading of the PV module 200. The bypass diodes are typically coupled so as to bypass every n cells where n can be between about 5 to about 20 or more PV cells. Any number of PV cells can be connected in parallel (e.g., 2, 3, 4, 5, or more). In one configuration 20 PV cells are coupled in parallel. As the number of PV cells are coupled in parallel, the current increases. As the current increases a larger conductor or wire is required to minimize resistance loss. It should be understood that the described embodiment of a full column of PV cells coupled in parallel is not required and that portions of the PV cells in a column could be coupled in parallel and then coupled in series with another portion of the PV cells in the same column.

By way of example, a first portion of the PV cells 202A-202n including PV cells 202A-202D could be coupled in parallel, and a second portion of PV cells including PV cells 202E-202H could be coupled in parallel, and a third portion of PV cells including PV cells 2021-202L could be coupled in parallel, and a fourth portion of PV cells including PV cells 202M-202P could be coupled in parallel. The first portion of the PV cells 202A-202n can then be coupled in series with the second portion of PV cells which is also coupled in series with the third portion of PV cells, which is also coupled in series with the forth portion of PV cells.

The parallel coupled PV cells are coupled by a first wire 215 coupling the respective bottom surface of each of the parallel coupled PV cells and a second wire couples the respective top surface of each of the parallel coupled PV cells. There is no requirement to lace the thin ribbon leads from a top surface of a first PV cell to a bottom surface of each adjacent PV cell. This simplifies assembly and allows use of a more efficient wire 214 of the top surfaces of the PV cells.

Referring to FIG. 2B, one embodiment of the improved PV module 200 is formed in five layers: a substrate layer 270, a bottom side wire layer 272, a PV cell layer 274, a top surface wire layer 276, and a top cover layer 278. The substrate layer 270 includes sealing substrate components as will be described elsewhere in more detail. The bottom side wire layer 272 includes the bottom side wires 215. The PV cell layer 274 includes the PV cells 202A-207n. The PV cell layer 274 also includes interconnecting wires 216 and 217. The top surface wire layer 276 includes the wires 214 on the top surfaces of the PV cells 202A-207n. The top cover layer 278 includes sealing top cover layer(s) as will be described elsewhere in more detail. Forming the PV module 200 in five layers simplifies the assembly and the wiring between the PV cells. It should be understood that each of the layers 270-278 can include more than one layer.

For series electrically coupled PV cells, the total current output of the entire series circuit is limited to the current output of the poorest performing PV cell. A significant advantage of the parallel coupled PV cells is that individual PV cell currents are additive. Therefore, if one parallel coupled PV cell has a poor current output it only affects the output of that PV cell and does not limit the total current output of the parallel coupled PV cells. As a result, the PV module performance is less vulnerable to variations in PV cell performance or external shadowing losses.

Referring again to FIG. 1A, flat metal ribbon leads 134 are predominately used to interconnect the PV cells 102A-110H in a PV module. The flat metal ribbon leads 134 cover significant portions of the photoactive area of the PV cells 102A-110H. This loss is referred to as shadowing loss. The shadowing loss reduces the power output and energy conversion efficiency of the PV cell.

One alternative for the flat metal ribbon leads 134 uses non-flat wires instead of the metal ribbon leads 134. The non-flat wires have a narrower width and a greater thickness than the typical flat metal ribbon leads 134. The non-flat wires can have a round or other cross section. Referring to FIG. 2D, a round cross-section wire 214 and a triangular cross-section wire 214′ are shown. For a given cross-sectional area, the non-flat wires can reduce the area shadowing loss, and thus improve PV cell electrical efficiency and output. The typical widths of the flat metal ribbon leads 134 is 2 mm wide and a thickness of about 0.2 mm yielding a cross-sectional area of about 0.4 sq mm. The non-flat wires can be made with a much larger cross sectional area than the metal ribbon leads 134 and therefore the non-flat wires are capable of carrying more current than the metal ribbon leads. For parallel cells, the non-flat wires are sized to conduct the corresponding current flow of the parallel coupled PV cells. By way of example, a 14 gauge wire has a diameter of 1.6 mm and a cross-sectional area equal to about 2 sq mm where area of a round wire is equal to Πr². Accordingly, the cross-section of a 14 gauge wire is many times larger than the cross sectional area of the flat metal ribbon leads 134 where the 14 gauge wire has less width and therefore covers less photovoltaically active area of the PV cells. Shaped wires having reflective surfaces where the light which normally strikes the wire is reflected onto the photovoltaic region of the PV cells further reduces the effective optical cross-section of the wire.

The non-flat wires can include substantially flat surfaces capable of reflecting any light that impinges on the wire onto the PV cells area. By way of example the light 150 impinging on the triangle cross section wire 214′ reflects the light 150′ to the PV cell 207E.

The non-flat wires 214 can be formed into any desired shape in a geometrical forming press or similar process as the PV cells and wiring 214 are installed in the PV module 200. This allows use of large scale commercially available round electrical wire and does not require custom or pre-fabricated wire. The non-flat wires 214 can be coated such as for aiding solderability or other purposes. The coating can also enhance the optically reflective properties of the wire 214 to more efficiently reflect the light 150 on to the PV cell. The coating can include a tin or solder plating or a shiny, reflective or polished light colored or metallic finish.

The increased height of the non-flat electrical wires 214 is compatible with cover film 225 and any additional layers 227. The cover film 225 conforms to the non-flat electrical wires 214 as shown in FIG. 2D. It should be understood that the relative thicknesses and dimensions shown in the drawings are not drawn to scale and proportions may be exaggerated so as to more clearly illustrate the portions of the disclosed elements.

If a rigid cover film 225 is used such as a front glass, polycarbonate, acrylic or other optically transparent cover materials, a pre-formed channel can be included in the rigid cover film 225. The pre-formed channel can accommodate the non-flat wires 214. The shape of the preformed channels can correspond to and can conform to the non-flat wires 214 and would be made consistent to maintain the reflective properties of the non-flat leads. The non-flat wires 214 can be incorporated into the rigid cover film 225 and attached to the PV cells 202A-207n as the rigid cover film 225 is applied to the PV module 200.

A similar manifestation is conceivable for the front cell grid lines. Small circular or other shaped wires could be used. The spacing of these grid wires would be defined in order to minimize PV cell electrical series resistance losses. The solar cell front surface could consist of a transparent conductive layer or other charge collecting layers.

Referring now to FIGS. 2E-2G, the grid lines 256A-256n and top surface wires 214 on an exemplary PV cell 202B. The cross section of the PV cell 202B in FIG. 2F shows the PV cell is formed from two layers of two different types of material 252 and 254. By way of example, layer 252 can be P-type material and layer 254 can be N-type material. The two layers 252 and 254 of two different types of material meet at a junction 255. Light reacts with the two types of material at the junction to produce a current flow from one layer across the junction 255 to the other layer. Thus one layer 252 is the positive terminal and one layer 254 is the negative terminal. Grid lines 256A-256n gather the current across the layer 254 and couple the current to the wires 214.

As described above with regard to the top surface wires 214, the gridlines can be reduced in width by use of added height thus reducing the surface area of the PV cell 202B covered by the grid lines. Similar to the top surface wires 214, the grid lines 256A-256n can be formed to include reflective surfaces that can reflect light to the top layer 254. Thus further reducing the effective photovoltaically active area consumed by the gridlines.

Referring again to FIG. 1B, the PV module 100 is connected to external electrical connections via the electrical junction box 118. The electrical junction box 118 can be located in a centerline or an edge of the PV module 100. The electrical junction box 118 as shown on the edge of the PV module 100 is typically electrically isolated and insulated from the frame 116. The electrical junction box 118 is electrically coupled to the PV cells 102A-110H. Electrically coupling the PV cells 102A-110H to the electrical junction box 118 requires additional wiring and assembly to install the wiring and to combine the connections in the electrical junction box 118.

The improved PV module 200 does not require a junction box. The external electrical connections 210, 212 to the improved PV module 200 are made using an electrical connector such as a stud, spade connector, socket or other suitable electrical connector. FIG. 4A is a detailed view of the electrical connector 212, in accordance with an embodiment of the present invention. FIG. 4B is a cross sectional view 4B-4B of the detailed view of the electrical connector 212, in accordance with an embodiment of the present invention. The electrical connector 212 can be mechanically attached to the metal backing plate 226 near a corner or edge of PV module 200. The electrical connector 212 can be a female type connector as shown. Alternatively, the electrical connector 212 can be a corresponding male type connector 412. The male connector 412 can be inserted into a recess 212′ in the female connector 212. The electrical connector 212 is electrically coupled to the PV cell 202A through a feed through 404 in the backing plate 226.

A latching mechanism 402 can be optionally included to secure the electrical connectors 212, 412 together. The latching mechanism 402 can be any suitable type of latch or even mechanical fastener such as a bolt, a pin or a latch. The latching mechanism 402 can be included inside the connector 212 or externally as shown.

FIG. 4C illustrates multiple improved PV modules 200A-n coupled together in an improved PV module array 430, in accordance with an embodiment of the present invention. The electrical connectors 212, 210 are on the edges or corners of the improved PV module 200, 200A-n. Placing the electrical connectors on the edge or corner of the improved PV module 200, 200A-n reduces the length of external cables 420A-n required to interconnect adjacent PV modules 200A-n. Placing the electrical connectors on the edge or corner of the improved PV module 200, 200A-n also reduces the non-flat wires 214 required within each of the improved PV modules 200.

In order to minimize torque on the PV cells 202A-207n and the wires 214 coupling the PV cells to the electrical connectors 210, 212, the connector 210, 212 can be made in a non-circular shape (e.g., slot, rectangle, triangle, etc.). The non-round hole can be part of the backing plate 226. The non-round hole can be punched in the back metal plate 226. The non-round hole can also provide an integrated strain relief.

### Photovoltaic Array Deployment

To achieve large-scale deployment of photovoltaic systems (e.g., 50-1000 megawatt or even greater) the photovoltaic array installation costs must be substantially reduced. Typically, the installed photovoltaic system costs two to three times the cost of the PV modules. Segmented support frames are laid out onsite and bolted together to hold the PV modules. This is required for many reasons including the requirement to support the typical PV module 100 by the frame 116. As the improved PV module 200 does not use a frame but instead relies on a self-supporting backing plate, the support structure required for deployment in an array of improved PV modules 430 can be substantially simplified and built of significantly reduced tolerance requirements. The simplification and the reduced tolerances allow further cost reduction in the deployment of the array of improved PV modules 430.

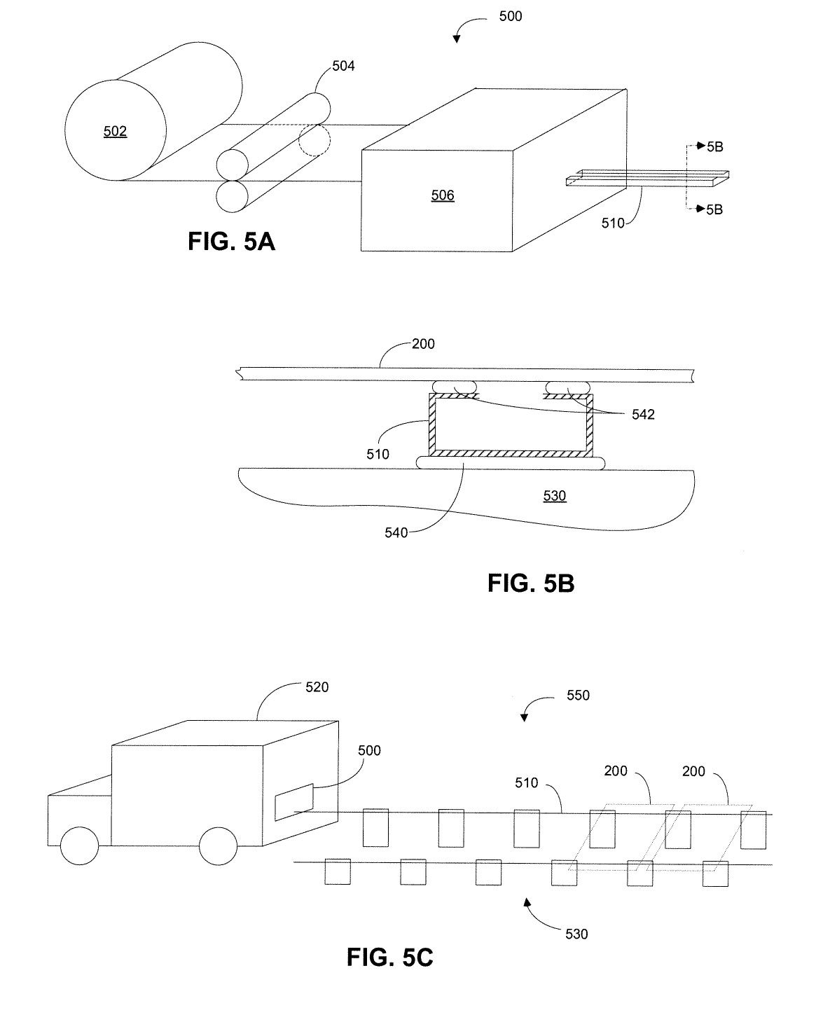

A forming system 500 can make continuous lengths of support members. By way of example, a roll of sheet material such as steel, aluminum, galvanized steel, stainless steel or similar materials and alloys thereof, can be formed into any desired shape and length as needed, on site. FIG. 5A is a simplified diagram of the support member forming system 500, in accordance with an embodiment of the present invention. FIG. 5B is a cross section of the support member 510, in accordance with an embodiment of the present invention. It should be understood that the formed cross section shape of the support member 510 is merely exemplary and any suitable formed shape can be used. Further it should be understood that the elements of the drawings are not drawn to scale.

FIG. 5C is a simplified diagram of a deployment system 550, in accordance with an embodiment of the present invention. The support member forming system 500 can be portable such as being part of a vehicle 520 SO that the support member 510 can be formed on site where the PV module array 430 will be deployed.

Forming the support member 510 into the desired shape and length as needed, on site substantially reduces the labor and materials required to assemble a support framework for a PV module 200 and saves even more labor and simplifies the assembly of an array of PV modules even further. By way of example, a 500 megawatt (MW) array of PV modules can be constructed of approximately 850 rows of interconnected PV modules 200 one-mile long each. Any combination of rows and PV module string lengths can be formed. By way of example, it may be necessary to optimize PV module array performance or to accommodate deployment constraints such as may be caused by terrain.

The PV module 200 can be attached to the module support member 510 using an adhesive 542 and/or an adhesive tape and/or a mechanical fastener and combinations thereof. By way of example an adhesive or adhesive tape could be used to provide a mechanical bond between the support member 510 and the PV module 200 and a mechanical fastener can also be used to electrically bond the PV module to the support member 510. The support member 510 can be grounded or coupled to another electrical potential as may be desired. Similarly, the module support member 510 can be secured to a foundation member 530 using mechanical fasteners including bolts, pins, latches or even an adhesive 540 as shown. By way of example, a foam adhesive tape such as 3M brand very high bond (VHB) tape can be used instead of more traditional mechanical fasteners such as rivets or screws or welding or nuts and bolts. The adhesive properties of the adhesives 540, 542 provide a sufficiently long bond integrity life under the environmental conditions where the PV modules 200 are deployed. An electrically conductive adhesive can be used to both mechanically bond and electrically couple the PV module 200 to the module support member 510. By way of example, an electrically conductive adhesive can electrically couple the PV module 200 to the module support member 510 such as for electrically coupling the PV module 200 to ground or another potential.

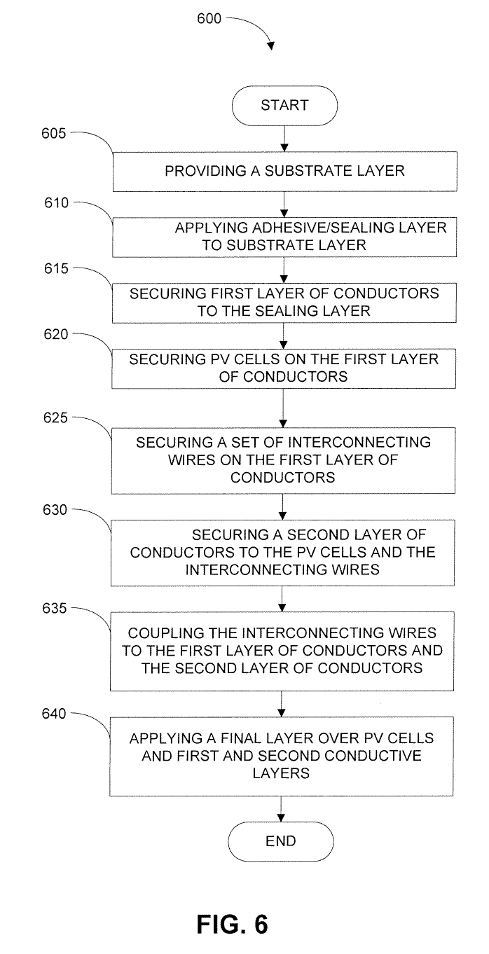

FIG. 6 is a flowchart of the method operations 600 of forming a photovoltaic module, in accordance with an embodiment of the present invention. The operations illustrated herein are by way of example, as it should be understood that some operations may have sub-operations and in other instances, certain operations described herein may not be included in the illustrated operations. It will be further appreciated that the instructions represented by the method operations 600 are not required to be performed in the order presented, and that all the processing represented by the operations may not be necessary to practice the invention. With this in mind, the method and operations 600 will now be described. In an operation 605, a substrate layer is provided. The substrate layer can be the backing plate 226 or can be a supporting optical layer such as a polycarbonate layer forming the top surface layer 225. An adhesive and/or sealing layer 226′ is applied to the substrate in an operation 610. The adhesive layer 226′ can also have a selected heat conductive property.

In an operation 615, a first layer of conductors is applied to the sealing layer. The first layer of conductors can be the top surface, non flat wires 214 or can be the bottom surface wires 215. In an operation 620 multiple PV cells 202A-207n are arranged on the first layer of conductors. The PV cells 202A-207n are arranged and at least portions of the PV cells are electrically coupled in parallel by the first layer of conductors as described above.

In an operation 625, a set of interconnecting wires 216, 217 are arranged on the first layer of conductors and in the same layer as the PV cells. The interconnecting wires 216, 217 can be as thick as the PV cells so as to be able to efficiently use the space and conduct the current required.

In an operation 630, a second layer of conductors are formed on a layer on the PV cells and interconnecting wires 216, 217. The second layer of conductors is also coupled to the PV cells.

In an operation 635, the interconnecting wires 216, 217 are coupled to the first layer of conductors and the second layer of conductors as described herein. In an operation 640, a final layer is applied over the PV cells and the conductive wires. The electrical connections between one or more of the conductor layers and/or the PV cells 202A-207n can be completed prior to placing the PV cells on the substrate or a supporting optical layer. The final layer can be a substrate layer or a conformal cover layer. It should be understood that the PV module 200 can be assembled in any suitable order and not limited to the order set forth herein. By way of example the conductive layers may be formed first, followed by the substrate layer and the PV cell interconnecting layer or any other suitable order.

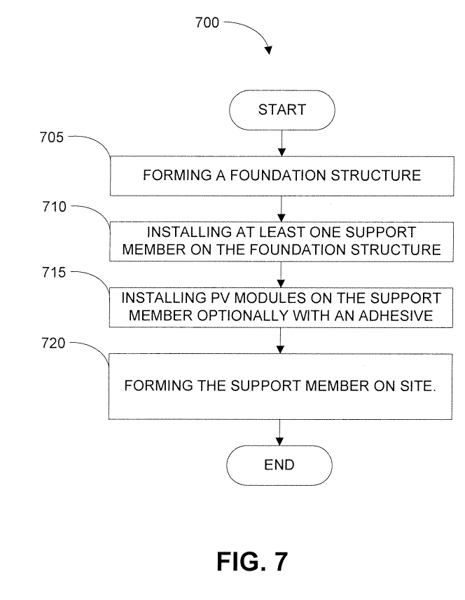

FIG. 7 is a flowchart of the method operations 700 of deploying a photovoltaic module, in accordance with an embodiment of the present invention. The operations illustrated herein are by way of example, as it should be understood that some operations may have sub-operations and in other instances, certain operations described herein may not be included in the illustrated operations. It will be further appreciated that the instructions represented by the method operations 700 are not required to be performed in the order presented, and that all the processing represented by the operations may not be necessary to practice the invention. With this in mind, the method and operations 700 will now be described. In an operation 705, a foundation structure 530 is formed and at least one support member 510 is installed on the foundation structure in an operation 710. The photovoltaic modules 200 are installed on the at least one support member in an operation 715. In an operation 720, the support member can be optionally formed on site, as needed in the desired length such as described in FIGS. 5A-5C above.

It will be further appreciated that the instructions represented by the operations in the above figures are not required to be performed in the order illustrated, and that all the processing represented by the operations may not be necessary to practice the invention. Although the foregoing invention has been described in some detail for purposes of clarity of understanding, it will be apparent that certain changes and modifications may be practiced within the scope of the appended claims. Accordingly, the present embodiments are to be considered as illustrative and not restrictive, and the invention is not to be limited to the details given herein, but may be modified within the scope and equivalents of the appended claims.

What is claimed is:

1. A method of forming a photovoltaic module comprising:
providing a first layer;
applying a first adhesive layer to the first layer;
securing a first layer of conductors on the sealing layer;
securing a plurality of photovoltaic cells on the first layer of conductors;
electrically coupling at least a portion of the photovoltaic cells in parallel;
securing a plurality of interconnecting conductors to the first layer of conductors;
securing a second layer of conductors to the photovoltaic cells and the plurality of interconnecting conductors;
electrically coupling the plurality of interconnecting wires to the first layer of conductors and the second layer of conductors, wherein in at least one of the first layer of conductors, the second layer of conductors and the plurality of interconnecting conductors are non-flat electrical wires; and
applying a final layer over the plurality of photovoltaic cells and the first layer of conductors, the interconnecting conductors and second layer of conductors.

2. The method of claim 1, wherein the non-flat conductors include at least one reflective surface.

3. The method of claim 2, wherein the reflective surface includes a reflective coating.

4. The method of claim 1, further comprising installing a positive electrical connector and a negative electrical connector on an opposing side of a backing plate from the plurality of photovoltaic cells.

5. The method of claim 4, wherein the positive and negative electrical connectors have a shape that substantially prevents torque to the plurality of photovoltaic cells.

6. The method of claim 1, wherein applying the final layer over the plurality of photovoltaic cells and the first layer of conductors, the interconnecting conductors and second layer of conductors includes sealing the plurality of photovoltaic cells and the first layer of conductors, the interconnecting conductors and second layer of conductors between the final layer and the first layer.

7. The method of claim 1, wherein the final layer includes more than one layer and wherein at least one of the more than one layer includes a second adhesive layer.

8. The method of claim 1, wherein the first adhesive layer supports and encapsulates the plurality of photovoltaic cells.

9. The method of claim 1, wherein at least one of the first layer or the final layer includes a first thermally conductive layer and wherein the first thermally conductive layer thermally couples the plurality of photovoltaic cells to an exterior surface of the photovoltaic module.

10. The method of claim 9, wherein the first thermally conductive layer is metallic and forms first exterior surface of the photovoltaic module opposite from a second exterior surface of the photovoltaic module and the second exterior surface of the photovoltaic module is oriented toward a light source.

11. The method of claim 9, wherein the first thermally conductive layer includes a second thermally conductive layer between the plurality of photovoltaic cells and the first thermally conductive layer.

12. The method of claim 11, wherein the second thermally conductive layer electrically insulates the plurality of photovoltaic cells from the first thermally conductive layer.

13. The method of claim 1, wherein the plurality of photovoltaic cells and the plurality of interconnecting conductors are formed in a first layer and the first layer of conductors are formed in a second layer adjacent to a first surface of the plurality of photovoltaic cells and the second layer of conductors are formed in a third layer adjacent to a second surface of the plurality of photovoltaic cells, the second surface of the plurality of photovoltaic cells being opposite from the first surface of the plurality of photovoltaic cells.

14. The method of claim 1, wherein at least one of the first layer or the final layer includes a conforming cover layer.

15. The method of claim 14, wherein the conforming cover layer conforms to the non-flat electrical wires.

16. The method of claim 1, wherein at least one of the first layer or the final layer includes cover layer over a photovoltaically active surface of the plurality of photovoltaic cells and wherein the cover layer includes recesses for the non flat wires on the photovoltaically active surface of the plurality of photovoltaic cells.

17. The method of claim 1, further comprising securing the photovoltaic module to a support member.

18. The method of claim 17, further comprising forming the support member on site.

19. A method of forming a large scale photovoltaic module array comprising:
forming at least one support member onsite;
securing the at least one support member to a foundation structure;
securing a plurality of photovoltaic modules to the at least one support member; and
electrically coupling the plurality of photovoltaic modules.

20. A method of connecting a plurality of photovoltaic cells comprising:
electrically coupling a first surface of the plurality of photovoltaic cells to a first conductive layer, the first surface of the plurality of photovoltaic cells having a first polarity; and
electrically coupling a second surface of the plurality of photovoltaic cells to a second conductive layer, the second surface of the plurality of photovoltaic cells having a second polarity, the second surface of the plurality of photovoltaic cells being opposite the first surface, wherein at least one of the first conductive layer or the second conductive layer includes non-flat electrical wires.

21. The method of claim 20, wherein the non-flat electrical wires include at least one optically reflective surface.22. A photovoltaic module comprising:
a first layer;
a first adhesive layer on the first layer;
a first layer of conductors on the sealing layer;
a plurality of photovoltaic cells on the first layer of conductors wherein the first layer of conductors electrically couple at least a portion of the photovoltaic cells in parallel;
a plurality of interconnecting conductors electrically coupled to the first layer of conductors;
a second layer of conductors electrically coupled to the photovoltaic cells and the plurality of interconnecting conductors, wherein in at least one of the first layer of conductors, the second layer of conductors and the plurality of interconnecting conductors are non-flat electrical wires; and
a final layer over the plurality of photovoltaic cells and the first layer of conductors, the interconnecting conductors and second layer of conductors.

23. The photovoltaic module of claim 22, wherein the non-flat conductors include at least one reflective surface.

24. The photovoltaic module of claim 23, wherein the reflective surface includes a reflective coating.

25. The photovoltaic module of claim 22, further comprising a positive electrical connector and a negative electrical connector on an opposing side of a backing plate from the plurality of photovoltaic cells.

26. The photovoltaic module of claim 25, wherein the positive and negative electrical connectors have a shape that substantially prevents torque to the plurality of photovoltaic cells.

27. The photovoltaic module of claim 22, wherein the final layer over the plurality of photovoltaic cells and the first layer of conductors, the interconnecting conductors and second layer of conductors includes a sealing layer.

28. The photovoltaic module of claim 22, wherein the final layer includes more than one layer and wherein at least one of the more than one layer includes a second adhesive layer.

29. The photovoltaic module of claim 22, wherein the first adhesive layer supports and encapsulates the plurality of photovoltaic cells.

30. The photovoltaic module of claim 22, wherein at least one of the first layer or the final layer includes a first thermally conductive layer and wherein the first thermally conductive layer thermally couples the plurality of photovoltaic cells to an exterior surface of the photovoltaic module.

31. The photovoltaic module of claim 30, wherein the first thermally conductive layer is metallic and forms first exterior surface of the photovoltaic module opposite from a second exterior surface of the photovoltaic module and the second exterior surface of the photovoltaic module is oriented toward a light source.

32. The photovoltaic module of claim 30, wherein the first thermally conductive layer includes a second thermally conductive layer between the plurality of photovoltaic cells and the first thermally conductive layer.

33. The photovoltaic module of claim 32, wherein the second thermally conductive layer electrically insulates the plurality of photovoltaic cells from the first thermally conductive layer.

34. The photovoltaic module of claim 22, wherein the plurality of photovoltaic cells and the plurality of interconnecting conductors are formed in a first layer and the first layer of conductors are formed in a second layer adjacent to a first surface of the plurality of photovoltaic cells and the second layer of conductors are formed in a third layer adjacent to a second surface of the plurality of photovoltaic cells, the second surface of the plurality of photovoltaic cells being opposite from the first surface of the plurality of photovoltaic cells.

35. The photovoltaic module of claim 22, wherein at least one of the first layer or the final layer includes conforming cover layer.

36. The photovoltaic module of claim 35, wherein the conforming cover layer conforms to the non-flat electrical wires.

37. The photovoltaic module of claim 22, wherein at least one of the first layer or the final layer includes cover layer over an photovoltaically active surface of the plurality of photovoltaic cells and where the cover layer includes recesses for the non flat wires on the photovoltaically active surface of the plurality of photovoltaic cells.

38. The photovoltaic module of claim 22, further comprising securing the photovoltaic module to a support member.

39. The photovoltaic module of claim 38, further comprising forming the support member on site.
